(19) United States
(12) Patent Application Publication
(10) Pub. No.: US 2011/0204213 A1
(43) Pub. Date: Aug. 25, 2011

(54) LIGHT AMPLIFICATION CIRCUIT AND PHOTOCOUPLER

(75) Inventors: Masafumi SHIMIZU, Shiga (JP); Setsuya OKU, Shiga (JP)

(73) Assignee: RENESAS ELECTRONICS CORPORATION, Kanagawa (JP)

(21) Appl. No.: 13/028,744

(22) Filed: Feb. 16, 2011

(30) Foreign Application Priority Data
Feb. 24, 2010 (JP) 2010-038445

(51) Int. Cl. H03F 3/08

(52) U.S. Cl. 250/214 LS

(57) ABSTRACT

A light amplification circuit includes a photodiode PD with an epi-sub structure, an I/V conversion circuit that converts current output from the PD into a voltage, and a correction circuit that removes charge and discharge current, which is cause by a parasitic capacitance of the photodiode, from current output from the PD between the PD and the I/V conversion circuit.

### CROSS-REFERENCE TO RELATED APPLICATIONS

This application is based upon and claims the benefit of priority from Japanese patent application No. 2010-038445, filed on Feb. 24, 2010, the disclosure of which is incorporated herein in its entirety by reference.

### BACKGROUND

1. Field of the Invention

The present invention relates to a light amplification circuit for converting photocurrent generated by a photodiode into a voltage, and particularly to a technique for preventing a malfunction by power supply variation.

2. Description of Related Art

A photocoupler that uses an open collector as an output is required to provide noise immunity in which the output does not malfunction when power supply voltage varies. Japanese Unexamined Patent Application Publication No. 2004-328061 discloses a technique to address the above issue. A light amplification circuit disclosed in Japanese Unexamined Patent Application Publication No. 2004-328061 includes a photodiode with a base-epi structure. However, in order to realize a low cost, it is preferable to use a photodiode with an epi-sub structure, which is suitable for smaller sizes, as a photodiode that occupies a larger area.

FIG. 4 exemplifies a light amplification circuit of a prior art. FIG. 5 shows a circuit configuration of both ends of a photodiode PD in the light amplification circuit shown in FIG. 4. An active element used in the circuit shown in FIG. 4 is only an NPN transistor. This circuit is an open collector output circuit. Usually, an external pull-up resistor is inserted between an output terminal OUT and a power supply line. This circuit includes an I/V conversion circuit 401, a voltage amplifier 402, a base current correction Ref amplifier 403, a PD cathode Ref amplifier 404, and an output transistor Q401. Resistors R503 and R506 of FIG. 5 respectively correspond to resistors R401 and R405 of FIG. 4.

In FIG. 4, in response to light entering to the PD, photocurrent ipd flows from the cathode to the anode of the PD, and is input to the I/V conversion circuit 401. At this time, as the resistor R401 will be a feedback resistor, the I/V conversion circuit 401 outputs a voltage Vo401, which is a voltage reduced by ipd×R501 from the state of ipd=0.

The voltage Vo401 is input to the voltage amplification amplifier 402. A voltage Vo402=Vo401×R503/R502 is generated from the state of ipd=0 by the influence of the feedback resistors R402 and R403. When the voltage Vo402 reaches Vf or more, which is a threshold voltage of Q401, Q401 is turned on and OUT becomes a low level.

Since an input to the I/V conversion circuit 401 is the base of an NPNBip transistor of a common emitter, base current is needed. As the current generated in the PD is as small as μA level, this base current needs to be corrected. The base current correction Ref amplifier 403 supplies current equivalent to the base current in order to correct an on and off levels. The amount of the current supply enables adjustment of the on and off levels.

Next, an operation of the PD cathode Ref amplifier 404 is explained. When variation is generated in the power supply voltage, a potential of each amplifier will also vary. At this time, Cpd exists in the PD as a parasitic capacitance (junction capacitance of the PD). Therefore, potential variation between the anode and the cathode of the PD deviates by the power supply voltage variation, and charge and discharge current corresponding to the Cpd is generated. When the charge and discharge current is input to the I/V conversion circuit 401, the same operation as when the ipd is input is performed. In other words, the circuit is turned on and off regardless of the existence of optical input to the PD, and a malfunction is generated. Therefore, it is necessary to prevent the malfunction caused by the power supply voltage variation by connecting the PD cathode Ref, which has the same configuration and the same constant as the I/V conversion circuit 401, to the cathode of the PD.

The I/V conversion circuit 401 and the PD cathode Ref amplifier 404 are explained with reference to FIG. 5. The basic configuration of the I/V conversion circuit 401 is explained as an example. The I/V conversion circuit 401 is an amplifier with a configuration of a grounded emitter and an emitter follower by NPN transistors Q501 and Q502. The R503 as a feedback resistor is connected to the emitter of Q502, and the base of Q501. The emitter of Q501 is connected to a ground terminal GND, and the collector is connected to a power supply terminal Vcc via a load resistor R501. The base of Q502 as an emitter follower is connected to a junction between the collector of Q501 and R501. The collector of Q502 is connected to the Vcc, and the emitter is connected to the GND via a resistor R502.

In the abovementioned configuration, since the circuit with the same configuration and the same constant is connected to the anode and the cathode of the PD, when there is power supply voltage variation generated, potential variation in the anode and the cathode will be the same. Therefore, the charge and discharge current is not generated in the parasitic capacitance Cpd of the PD, and a malfunction does not occur.

By the way, there is an increasing need for a lower cost of photocouplers in recent years. In order to meet such a request, it is effective to reduce the PD which occupies a large ratio in the chip area. However, in the above configuration of the related art, when the PD with the base-epi structure is reduced, the amount of light entering the PD is reduced by the same amount light of LED. Therefore, it is necessary to increase the feedback resistor of the I/V amplifier, which generates a problem of being unable to respond to higher speed.

By the PD with the epi-sub structure, it is possible to generate more ipd than the base-epi structure when the same amount of light enters to the same area. Accordingly, the chip can be reduced without sacrificing higher speed. The principle is explained with reference to FIGS. 6 and 7.

FIG. 6 shows the PD with the base-epi structure. In this PD, a base layer P will be the anode and an epilayer N will be the cathode. The incident light contributes to the ipd from the base layer to the epilayer, and the light entered to the sub will not contribute. FIG. 7 shows the PD with the epi-sub structure. In the PD, an epilayer N will be the cathode and a sub layer P will be the anode. The incident light contributes as ipd from the epilayer to the sub layer, and most incident light contributes. Accordingly, the PD with the epi-sub structure can generate more ipd than the PD with the base-epi structure, and the area required to obtain the same ipd is relatively small. To be exact, as shown in FIG. 8, light contribution relates to a wavelength of light and a depth direction of Si.

### SUMMARY

However, as the sub will always be the lowest potential (GND) in the structure of BipIC, the anode will always be a GND potential in the PD with the abovementioned epi-sub structure. FIG. 9 shows an example of a circuit configuration when the PD with the epi-sub structure is applied to the light amplification circuit shown in FIG. 4. In the case of the PD with the epi-sub structure, as the I/V conversion circuit 901 is connected to the cathode of the PD with the epi-sub structure, the direction of the ipd generated when light entered will be opposite to the case of using the PD with the base-epi structure shown in FIG. 4. Therefore, in order to match the logic of an output, an inverter circuit 904, and an inverting amplifier composed of feedback resistors R905 and R907 is inserted, and the PD cathode Ref amplifier 404 is eliminated. The base current correction Ref amplifier 903 functions in a similar manner as the base current correction Ref amplifier 403. Other operations are the same as those of the case of FIG. 4.

However, in the configuration shown in FIG. 9, although the cathode of the PD is connected to the amplifier, the anode is connected to the GND. Therefore, a cathode potential varies by the power supply variation, but the GND potential does not vary, and the charge and discharge current by the parasitic capacitance Cpd of the PD is generated, which causes a malfunction.

FIGS. 10A to 10D illustrate waveforms at the time of normal and malfunction operations in the photodiode with the epi-sub structure. In this example, the power supply voltage Vcc varies as illustrated. FIG. 10A shows a normal waveform in the state where the output is low. FIG. 10B shows a normal waveform in the state where the output is high. When a malfunction occurs, a waveform which should be in a low level will be a high level as shown in FIG. 10C, or a waveform which should be in a high level will be a low level as shown in FIG. 10D.

A first exemplary aspect of the present invention is a light amplification circuit that includes a photodiode with an epi-sub structure, an I/V conversion circuit that converts current output from the photodiode into a voltage, and a correction circuit that removes charge and discharge current caused by a parasitic capacitance of the photodiode from current output from the photodiode between the photodiode and the I/V conversion circuit.

A second exemplary aspect of the present invention is a photocoupler comprising a light amplification circuit. The light amplification circuit includes a photodiode with an epi-sub structure, an I/V conversion circuit that converts current output from the photodiode into a voltage, and a correction circuit that removes charge and discharge current caused by a parasitic capacitance of the photodiode from current output from the photodiode between the photodiode and the I/V conversion circuit.

According to the abovementioned aspects, the charge and discharge current generated due to the parasitic capacitance of the photodiode with the epi-sub structure flows to the cathode of the photodiode, which is an input to the I/V conversion circuit. Accordingly, the charge and discharge current caused by the parasitic capacitance is cancelled out.

According to the present invention, even in the case of using the photodiode with the epi-sub structure, the influence of the charge and discharge current caused by the parasitic capacitance of the photodiode is eliminated and thereby preventing the malfunction by the power supply voltage variation.

### BRIEF DESCRIPTION OF THE DRAWINGS

The above and other exemplary aspects, advantages and features will be more apparent from the following description of certain embodiments taken in conjunction with the accompanying drawings, in which:

FIG. 1 shows a configuration of a light amplification circuit according to a first embodiment of the present invention;

FIG. 2 is a view showing a configuration of an I/V conversion circuit and a base current compensation Ref amplifier in the light amplification circuit according to the first embodiment;

FIG. 3 shows a configuration of a photocoupler according to a second embodiment of the present invention;

FIG. 4 illustrates a configuration of a light amplification circuit according to a prior art;

FIG. 5 illustrates a circuit configuration of both ends of a photodiode in the light amplification circuit shown in FIG. 4;

FIG. 6 illustrates a photodiode with the base-epi structure according to a prior art;

FIG. 7 illustrates the photodiode with the epi-sub structure according to a prior art;

FIG. 8 illustrates a region where incident light contributes as ipd in the photodiodes of the base-epi structure and the epi-sub structure according to the prior art;

FIG. 9 exemplifies a configuration when the photodiode with the epi-sub structure is applied to the light amplification circuit shown in FIG. 4; and

FIGS. 10A-10D exemplify waveforms at the time of a normal operation and a malfunction in the photodiode with the epi-sub structure according to a prior art.

### DETAILED DESCRIPTION

### First Embodiment

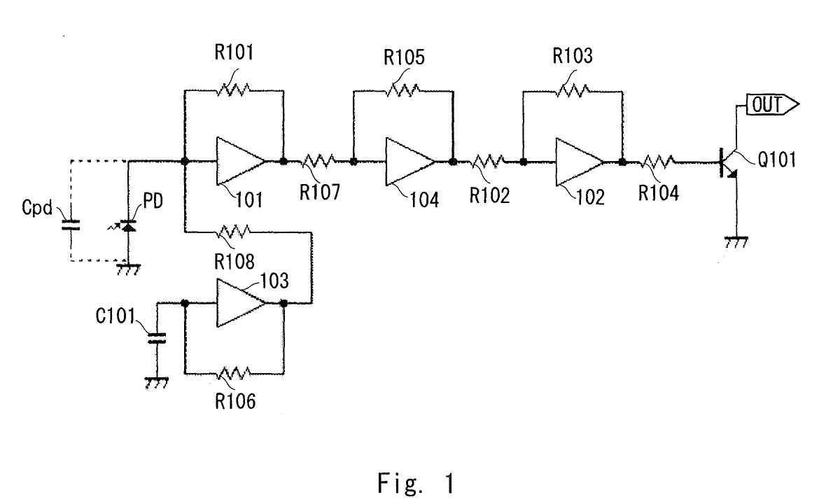

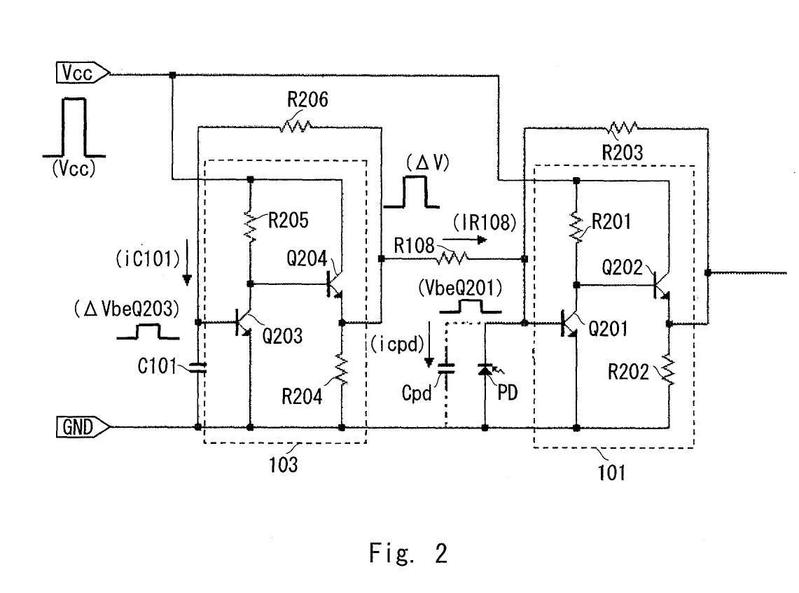

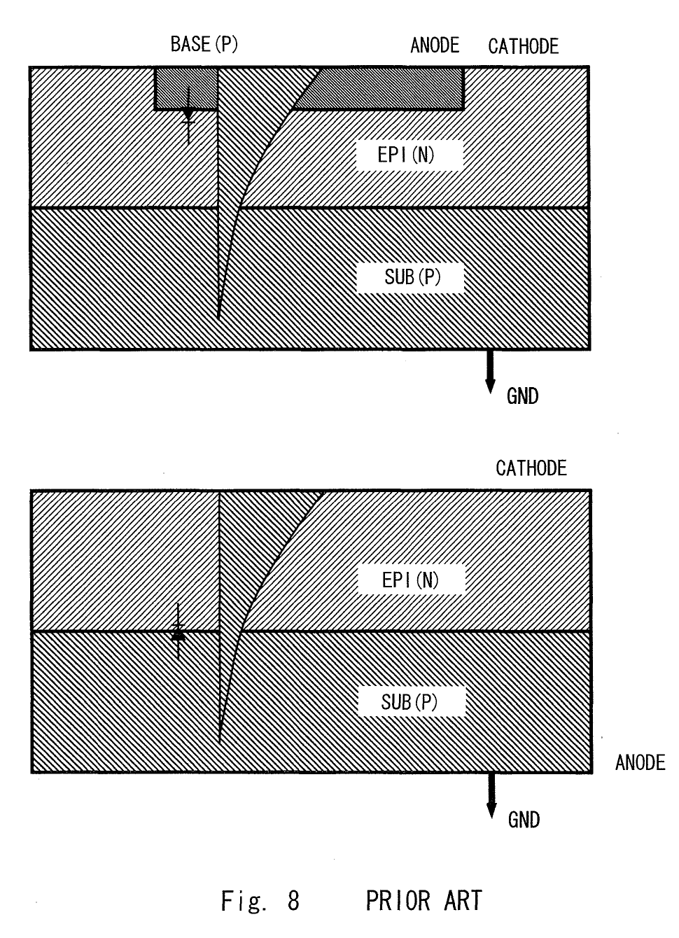

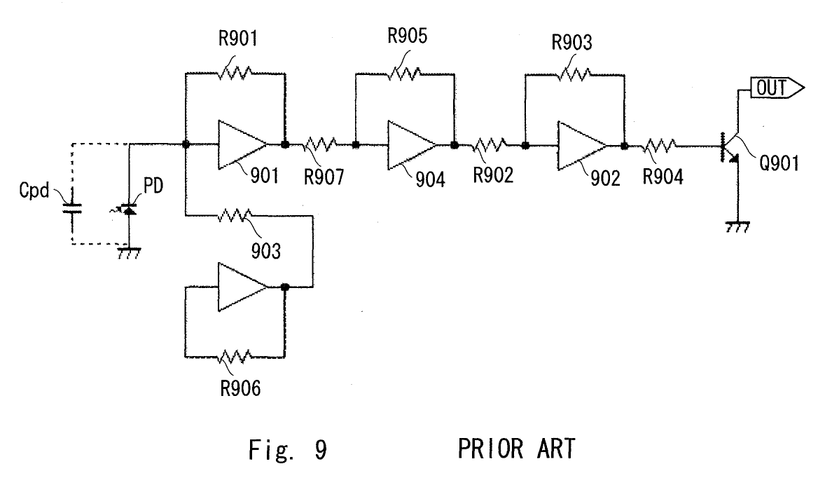

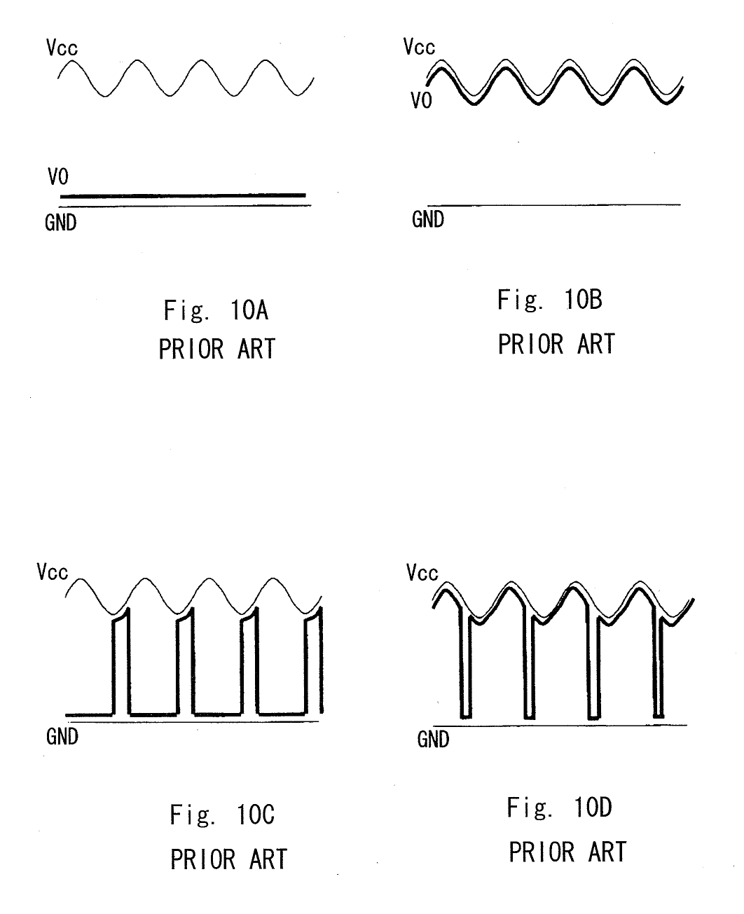

Hereinafter, embodiments of the present invention are described with reference to the drawings. FIG. 1 shows a configuration of a light amplification circuit according to the embodiment of the present invention. The light amplification circuit includes an I/V conversion circuit 101, an inverter circuit 104, a voltage amplification amplifier 102, a base current correction Ref amplifier 103, and an output transistor Q101. A difference from the light amplification circuit shown in FIG. 9 is that a capacitor C101 with the same capacitance value as the parasitic capacitance Cpd (junction capacitance of a PD) of the photodiode PD is also input to the base current correction Ref amplifier 103. Since the cathode of the PD is connected to the base of an NPN transistor Q201 (see FIG. 2) and the anode is connected to a GND, a reverse bias of the PD is determined by a built-in voltage Vf between the base and the emitter of Q201, and is almost constant. Therefore, Cpd can be considered to be equivalently a fixed capacitor.

FIG. 2 shows a configuration of the I/V conversion circuit 101 and the base current correction Ref amplifier 103. In the I/V conversion circuit 101, the emitter of the NPN transistor Q201 is connected to the GND, and the collector is connected to a power supply terminal Vcc via a resistor R201. The base of the NPN transistor Q202 is connected to a junction between the collector of the NPN transistor Q201 and the resistor R201. The collector of the NPN transistor Q202 is connected to the power supply terminal Vcc, and the emitter is connected to the GND via a resistor R202. A junction between the emitter of the NPN transistor Q202 and the resistor R202 will be an output from the I/V conversion circuit 101. The junction is connected to the subsequent stage and also connected to the base of the NPN transistor Q201 via the feedback resistor R203. The cathode of the PD is connected to the base of the NPN transistor Q201, and the anode of the PD is connected to the GND.

Since the base current correction Ref amplifier 103 is configured in a similar manner as the I/V conversion circuit 101, the explanation is omitted. The differences between 101 and 103 are that the capacitor C101 is connected to the base of NPN transistor Q203, and the other end of the capacitor C101 is connected to the GND. Another difference is that a resistor R108 is connected to the base of the NPN transistor Q201, which is an input of the I/V conversion circuit 101, from a junction between the emitter of the NPN transistor Q204 and a resistor R204. The resistors R203 and R206 of FIG. 2 respectively correspond to resistors R101 and R106 of FIG. 1.

An operation of the light amplification circuit according to this embodiment is explained with reference to FIG. 1. When the power supply voltage varies, the cathode potential of the PD, which is an input potential of the I/V conversion circuit 101, varies, and the charge and discharge current of the parasitic capacitance Cpd of the PD is generated. This charge and discharge current causes a malfunction. In a light-receiving amplifier according to this embodiment, the capacitor C101 with the same value as the parasitic capacitance Cpd of the PD is added between the input of the base current correction Ref amplifier 103 and the GND. When the I/V conversion circuit 101 and the base current correction Ref amplifier 103 have the same configuration and the same constant, the same amount of variation as the cathode potential of the PD is generated in the input potential of the base current correction Ref amplifier 103 and the potential of the capacitor C101. The same charge and discharge current as the charge and discharge current of the parasitic capacitance Cpd of the PD is generated in the capacitor C101, charge and discharge current icpd to the parasitic capacitance Cpd of the PD is complemented, and thereby preventing the malfunction by the variation in the power supply voltage.

Furthermore, an operation of the light amplification circuit according to this embodiment is explained with reference to FIG. 2. The voltage variation applied to the cathode of the PD by the power supply voltage variation ΔVcc shall be ΔVbeQ201, and the charge and discharge current generated in response in the parasitic capacitance Cpd of the PD shall be icpd. Moreover, the voltage variation applied to the capacitor C101 by the similar power supply voltage variation shall be ΔVbeQ203, and the charge and discharge current generated in response in the capacitor C101 shall be iC101.

Since the I/V conversion circuit 101 and the base current correction Ref amplifier 103 are the same circuits, and the parasitic capacitance Cpd and the capacitor C101 of the PD have the same value, the following formula is satisfied.

ΔVbeQ201=ΔVbeQ203

icpd=iC101

When the voltage variation generated by the iC101 in the emitter of the NPN transistor Q204, which is an output from the base current correction Ref amplifier 103, is ΔV, the same potential difference is generated in the resistors R206 and R108 as shown below.

ΔV−ΔVbeQ203=ΔV−ΔVbeQ201

When the resistors R206 and R108 have the same value and the current flowing to the resistor R108 is IR108, the following formula is satisfied.

iC101=IR108=icpd

Accordingly, the charge and discharge current icpd to the parasitic capacitance Cpd of the PD can be complemented, and the malfunction due to the power supply voltage variation can be prevented.

### Second Embodiment

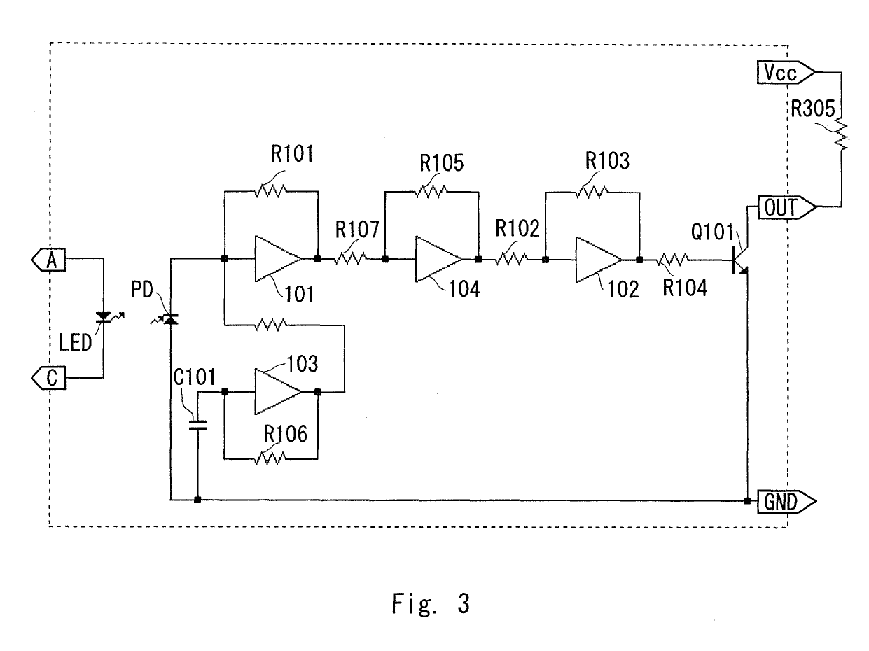

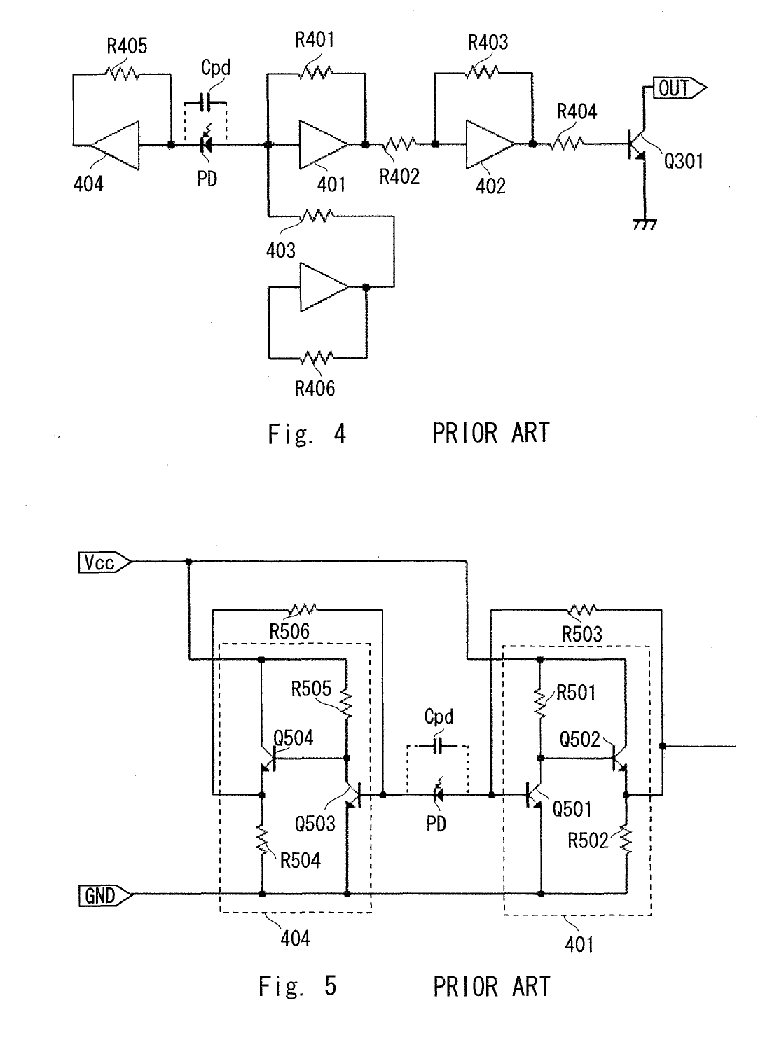

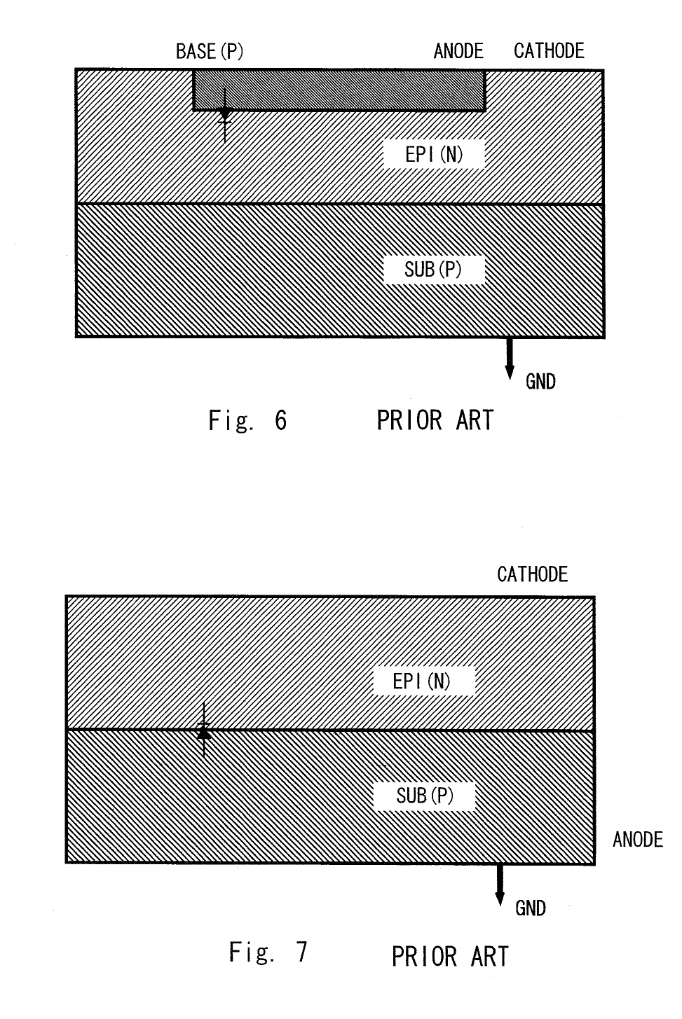

FIG. 3 shows a configuration of a photocoupler according to a second embodiment of the present invention. This photocoupler uses the light amplification circuit according to the abovementioned first embodiment, and an LED is placed in the opposed position of the PD as a light input to the PD. Moreover, an output is an open collector and a R305 as a pull-up resistor is connected between the output terminal OUT terminal and the power supply terminal Vcc. An operation of each amplifier is similar to that of the first embodiment. Accordingly, the charge and discharge current icpd to a parasitic capacitance Cpd of the PD can be complemented, and the malfunction by the power supply voltage variation can be prevented.

The first and second embodiments can be combined as desirable by one of ordinary skill in the art.

While the invention has been described in terms of the embodiment, those skilled in the art will recognize that the invention can be practiced with various modifications within the spirit and scope of the appended claims and the invention is not limited to the examples described above.

Further, the scope of the claims is not limited by the embodiments described above.

Furthermore, it is noted that, Applicant's intent is to encompass equivalents of all claim elements, even if amended later during prosecution.

What is claimed is:

1. A light amplification circuit comprising:
a photodiode with an epi-sub structure;
an I/V conversion circuit that converts current output from the photodiode into a voltage; and
a correction circuit that removes charge and discharge current from current output from the photodiode between the photodiode and the I/V conversion circuit, the charge and discharge current being caused by a parasitic capacitance of the photodiode.

2. The light amplification circuit according to claim 1, wherein the correction circuit comprises a capacitor including a capacitance corresponding to the parasitic capacitance.

3. The light amplification circuit according to claim 2, wherein the correction circuit further comprises a capacitor including a same value as the parasitic capacitance in addition to a same element configuration as the I/V conversion circuit.

4. The light amplification circuit according to claim 3, wherein
the I/V conversion circuit comprises a first NPN transistor including a base connected to a cathode of the photodiode, an emitter connected to a GND, and a collector connected to a power supply,
the correction circuit comprises a second NPN transistor including a base connected to the GND via the capacitor, an emitter connected to the GND, and a collector connected to the power supply, and
an output of the correction circuit and an input of the I/V conversion circuit are connected via a resistor including a same value as a feedback resistor inside the correction circuit.

5. A photocoupler comprising a light amplification circuit, wherein the light amplification circuit comprises:
a photodiode with an epi-sub structure;
an I/V conversion circuit that converts current output from the photodiode into a voltage; and
a correction circuit that removes charge and discharge current from current output from the photodiode between the photodiode and the I/V conversion circuit, the charge and discharge current being caused by a parasitic capacitance of the photodiode.
